(19) United States
(12) Patent Application Publication
(10) Pub. No.: US 2016/0326646 A1
(43) Pub. Date: Nov. 10, 2016

(54) METHOD FOR FORMING MANGANESE-CONTAINING FILM

(71) Applicant: TOKYO ELECTRON LIMITED, Tokyo (JP)

(72) Inventors: Kenji MATSUMOTO, Nirasaki-shi (JP); Kaoru MAEKAWA, Albany, NY (US); Tatsufumi HAMADA, Nirasaki-shi (JP); Hiroyuki NAGAI, Nirasaki-shi (JP)

(21) Appl. No.: 15/212,774

(22) Filed: Jul. 18, 2016

Related U.S. Application Data
(62) Division of application No. 14/566,807, filed on Dec. 11, 2014.
Application No. 14/566,807 is a continuation of application No. PCT/JP2013/066264, filed on Jun. 12, 2013.

(30) Foreign Application Priority Data
Jun. 18, 2012 (JP) 2012-137051

(51) Int. Cl. C23C 16/455; C23C 16/40; C23C 14/14; C23C 14/34; H01L 21/768; C23C 16/02; H01L 21/02; H01L 21/285; H01L 21/3105; C23C 16/18; C23C 16/48

(52) U.S. Cl. CPC C23C 16/45553; C23C 16/18; C23C 16/401; C23C 16/40; C23C 14/14; C23C 14/34; C23C 16/45527; C23C 16/481; C23C 16/02; H01L 21/02271; H01L 21/28556; H01L 21/02175; H01L 21/02126; H01L 21/3105; H01L 21/76831; H01L 21/76846

(57) ABSTRACT

A method for forming a manganese-containing film to be formed between an underlayer and a copper film includes reacting a manganese compound gas with a nitrogen-containing reaction gas to form a nitrogen-containing manganese film on the underlayer; and reacting a manganese compound gas with a reducing reaction gas, thermally decomposing a manganese compound gas, or performing a decomposition reaction on a manganese compound gas through irradiation of energy or active species to form a metal manganese film on the nitrogen-containing manganese film.

### CROSS-REFERENCE TO RELATED APPLICATIONS

This Divisional application is based upon and claims the benefit of an application Ser. No. 14/566,807, filed Dec. 11, 2014, which is a Continuation application of PCT International Application No. PCT/JP2013/066264, filed Jun. 12, 2013, which claimed the benefit of Japanese Patent Application No. 2012-137051, filed Jun. 18, 2012, the entire content of each of which is hereby incorporated by reference.

### TECHNICAL FIELD

The present disclosure generally relates to a method for forming a manganese-containing film.

### BACKGROUND

Along with the increase in the integration density of a semiconductor device, the geometrical dimension of a semiconductor device and internal wires has been steadily miniaturized. As the geometrical dimension of the internal wires, e.g., copper wires, becomes smaller, an increase in the resistance occurs due to the thin wire effect. In order to suppress the increase in the resistance, it is required to make a thickness of a diffusion-preventing film (hereinafter referred to as a barrier layer) for preventing diffusion of Cu narrower to reduce composite resistance of the barrier layer and the Cu wires. The barrier layer is formed by a physical vapor deposition (PVD) method (e.g., a sputter method).

However, when a thin barrier layer is formed by the PVD method, if the geometrical dimension of Cu wires is reduced to, e.g., 45 nm or less, step coverage begins to deteriorate when forming a film in grooves for burying the Cu wires. For that reason, in the future, it will become difficult to continuously form a thin barrier layer using the PVD method.

In contrast, a CVD method has better step coverage at a concave portion than that of the PVD method. Thus, the CVD method draws attention as a new method for forming a barrier layer. A manganese oxide film formed using the CVD method shows good step coverage for fine grooves and a high barrier property even if the thickness thereof is thin. Furthermore, as a film-forming temperature of the manganese oxide film is set at 100 degrees C. to 400 degrees C., the adhesion of the manganese oxide film with Cu existing thereon becomes good.

The barrier layer formed with a manganese oxide film exhibits a certain degree of adhesion with respect to Cu. In general, however, it cannot be said that an oxide shows good adhesion with respect to Cu. Although the barrier layer shows good step coverage for grooves and exhibits a high barrier property, it may be necessary to improve the adhesion with Cu.

### SUMMARY

The present disclosure provides some embodiments of a method for forming a film containing manganese, which is capable of improving the adhesion of the film with Cu.

According to one embodiment of the present disclosure, there is provided a method for forming a manganese-containing film to be formed between an underlayer and a copper film, including: reacting a manganese compound gas with a nitrogen-containing reaction gas to form a nitrogen-containing manganese film on the underlayer; and reacting a manganese compound gas with a reducing reaction gas, thermally decomposing a manganese compound gas, or performing a decomposition reaction on a manganese compound gas through irradiation of energy or active species to form a metal manganese film on the nitrogen-containing manganese film.

According to another embodiment of the present disclosure, there is provided a method for forming a manganese-containing film to be formed between an underlayer and a copper film, including: reacting a manganese compound gas with oxygen supplied from the underlayer to form a manganese oxide film or a manganese silicate film on the underlayer; and reacting a manganese compound gas with a reducing reaction gas, thermally decomposing a manganese compound gas, or performing a decomposition reaction on a manganese compound gas through irradiation of energy or active species to form a metal manganese film on the manganese oxide film or on the manganese silicate film.

According to a further embodiment of the present disclosure, there is provided a method for forming a manganese-containing film to be formed between an underlayer and a copper film, including: reacting a manganese compound gas with a reducing reaction gas, thermally decomposing a manganese compound gas, or performing a decomposition reaction on a manganese compound gas through irradiation of energy or active species to form a metal manganese film on the underlayer; and reacting a manganese compound gas with a nitrogen-containing reaction gas to form a nitrogen-containing manganese film on the metal manganese film.

According to still another embodiment of the present disclosure, there is provided a method for forming a manganese-containing film to be formed between an underlayer and a copper film, including: reacting a manganese compound gas with oxygen supplied from the underlayer to form a manganese oxide film or a manganese silicate film on the underlayer; and reacting a manganese compound gas with a nitrogen-containing reaction gas to form a nitrogen-containing manganese film on the manganese oxide film or one the manganese silicate film.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A to 1E are sectional views illustrating one example of a method for forming a manganese-containing film according to a first embodiment of the present disclosure.

FIGS. 2A to 2E are sectional views illustrating one example of a method for forming a manganese-containing film according to a second embodiment of the present disclosure.

FIGS. 3A to 3D are sectional views illustrating one example of a method for forming a manganese-containing film according to a third embodiment of the present disclosure.

FIGS. 4A to 4D are sectional views illustrating one example of a method for forming a manganese-containing film according to a fourth embodiment of the present disclosure.

FIGS. 5A to 5D are sectional views illustrating one example of a semiconductor device manufacturing method which makes use of methods for forming a manganese-containing film according to the first to fourth embodiments.

FIG. 6 is a plane view schematically illustrating one example of a film-forming system which can implement the methods for forming a manganese-containing film according to the embodiments of the present disclosure.

FIG. 7 is a sectional view schematically illustrating one example of a manganese CVD apparatus.

FIG. 8 is a view illustrating vapor pressures of water (H₂O) and ammonia (NH₃).

### DETAILED DESCRIPTION

Embodiments of the present disclosure will now be described in detail with reference to the accompanying drawings. In the following description, identical parts will be designated by like reference numerals throughout the drawings.

### First Embodiment

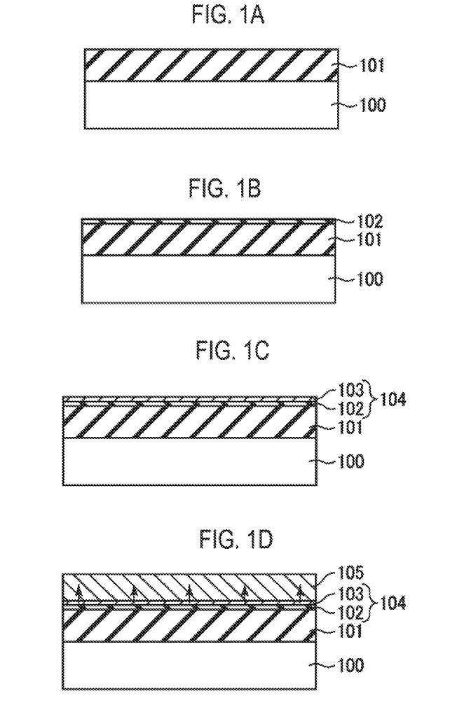

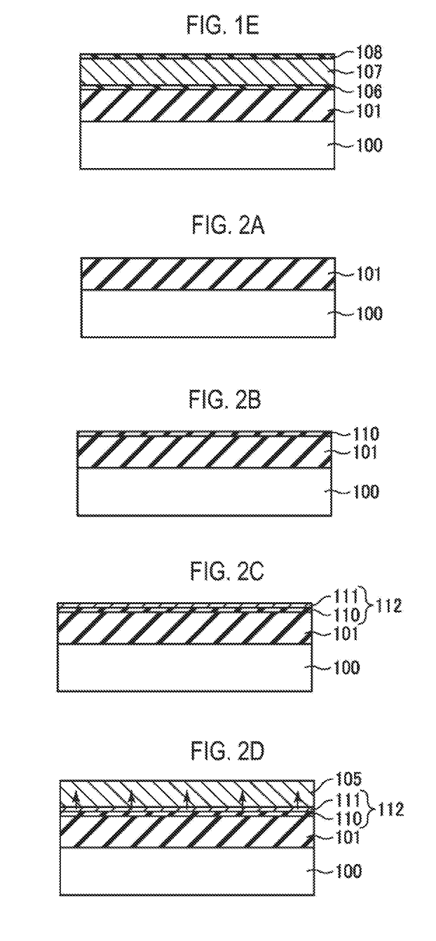

FIGS. 1A to 1E are sectional views showing one example of a method for forming a manganese-containing film according to a first embodiment of the present disclosure. First, as illustrated in FIG. 1A, for example, TEOS as a source gas is supplied to form a silicon oxide film 101 on a silicon substrate 100 by a CVD method. The silicon oxide film 101 is an insulation film that serves as, e.g., an inter-layer insulation film, in a semiconductor integrated circuit device. In the present embodiment, the silicon oxide film 101 is a film that becomes an underlayer film on which a manganese-containing film is formed. The insulation film serving as an inter-layer insulation film is not limited to the silicon oxide film (SiO₂) 101. A silicon-containing insulation film (a low-k film) of which relative permittivity is lower than that of SiO₂, such as SiOC, SiOCH or the like, may be used as the insulation film. Also, the insulation film may include a porous low-k film having pores. This is the same in all the embodiments to be described below. In the description of the embodiments, a process for making the surroundings of a transistor, namely the FEOL (Front End of Line), is omitted.

Then, as illustrated in FIG. 1B, a manganese compound gas and a nitrogen-containing reaction gas are supplied onto the silicon oxide film 101, and these gases are reacted with each other, thereby forming a nitrogen-containing manganese film 102 by a CVD method.

Then, as illustrated in FIG. 1C, a manganese compound gas and a reducing reaction gas are supplied onto the nitrogen-containing manganese film 102, and then reacted with each other, thereby forming a metal manganese film 103 by a CVD method. Alternatively, a manganese compound gas is supplied onto the nitrogen-containing manganese film 102 and then thermally decomposed, thereby forming a metal manganese film 103 by a CVD method. Alternatively, a manganese compound gas is supplied onto the nitrogen-containing manganese film 102 and then decomposed through irradiation of energy or active species, thereby forming a metal manganese film 103 by a CVD method.

A manganese-containing film 104 of the present embodiment is formed with the nitrogen-containing manganese film 102 and the metal manganese film 103.

When forming the nitrogen-containing manganese film 102, the following gases may be appropriately used.

(a1) an ammonia (NH₃) gas,

(a2) a hydrazine (NH₂NH₂) gas,

(a3) an amine (denoted by a chemical formula NR¹R²R³) gas, or

(a4) a hydrazine derivative (denoted by a chemical formula R¹R²NNR³R⁴) gas, where the R¹, R², R³ and R⁴ are hydrocarbon groups.

Examples of the amine gas (a3) include:

a methylamine (CH₃NH₂) gas—primary amine,

an ethylamine (C₂H₅NH₂) gas—primary amine,

a dimethylamine ((CH₃)₂NH) gas—secondary amine, and

a trimethylamine ((CH₃)₃N) gas—tertiary amine.

Examples of the hydrazine derivative gas (a4) include:

a methylhydrazine (CH₃NNH₃) gas,

a dimethylhydrazine ((CH₃)₂NNH₂) gas, and

a trimethylhydrazine ((CH₃)₃NNH) gas.

Among the hydrazine derivative gases (a4), the methylhydrazine gas has a boiling point of about 87 degrees C. and a relatively high vapor pressure. Thus, the methylhydrazine has an advantage in that it can be supplied with ease. Moreover, the methylhydrazine is an organic substance safer than hydrazine and is easily decomposable. From this viewpoint, the methylhydrazine is a material that can become one of nitrogen supply sources effective in carrying out the present disclosure.

When forming the metal manganese film 103, the following gases may be appropriately used.

(b1) a hydrogen (H₂) gas,

(b2) a carbon monoxide CO) gas,

(b3) an aldehyde (R—CHO) gas, or

(b4) a carboxylic acid (R—COOH) gas, where the R is an alkyl group denoted by —CₙH₂ₙ₊₁ (n is an integer equal to or greater than 0).

Examples of the aldehyde gas (b3) include:
a formaldehyde (HCHO) gas.

Examples of the carboxylic acid gas (b4) include:
a formic acid (HCOOH) gas.

Also, when forming the nitrogen-containing manganese film 102 and the metal manganese film 103, the following gases may be appropriately used.

(c1) a cyclopentadienyl-based manganese compound gas (denoted by a chemical formula Mn(RC₅H₄)₂).

(c2) a carbonyl-based manganese compound gas,

(c3) a beta-diketone-based manganese compound gas,

(c4) an amidinate-based manganese compound gas (denoted by a chemical formula Mn(R¹N—CR³—NR²)₂), or

(c5) an amideaminoalkane-based manganese compound gas (denoted by a chemical formula Mn(R¹N—Z—NR²₂)₂), where the R, R¹, R² and R³ are alkyl groups denoted by —CₙH₂ₙ₊₁ (n is an integer equal to or greater than 0) and the Z is an alkylene group denoted by —CₙH₂ₙ— (n is an integer equal to or greater than 0).

Examples of the cyclopentadienyl-based manganese compound gas (c1) include:
a bis(alkylcyclopentadienyl) manganese gas.

Examples of the carbonyl-based manganese compound gas (c2) include:
a decacarbonyldimanganese (Mn₂(CO)₁₀) gas,
a methylcyclopentadienyl tricarbonyl manganese ((CH₃C₅H₄)Mn(CO)₃) gas,
a cyclopentadienyl tricarbonyl manganese ((C₅H₅)Mn(CO)₃) gas,
a methylpentacarbonyl manganese (CH₃)Mn(CO)₅) gas, and
a 3-(t-BuAllyl)Mn(CO)₄ gas.

Examples of the beta-diketone-based manganese compound gas (c3) include:
a bis(dipivaloylmethanato) manganese (Mn(C₁₁H₁₉O₂)₂) gas,
a tris(dipivaloylmethanato) manganese (Mn(C₁₁H₁₉O₂)₃) gas,
a bis(pentanedione) manganese (Mn(C₅H₇O₂)₂) gas,
a tris(pentanedione) manganese (Mn(C₅H₇O₂)₃) gas,
a bis(hexafluoroacetyl) manganese (Mn(C₅HF₆O₂)₂) gas, and
a tris(hexafluoroacetyl) manganese (Mn(C₅HF₆O₂)₃) gas.

Examples of the amidinate-based manganese compound gas (c4) include:
a bis(N,N′-dialkylacetamininate) manganese gas.

Examples of the amideaminoalkane-based manganese compound gas (c5) include:
a bis(N,N′-1-alkylamide-2-dialkylaminoalkane) manganese gas.

A manganese compound gas disclosed in the specification of U.S. Patent Application Publication No. US2009/0263965A1 can be used as the amidinate-based manganese compound gas (c4).

A manganese compound gas disclosed in International Publication No. 2012/060428 can be used as the amideaminoalkane-based manganese compound gas (c5). Accordingly, the specification of U.S. Patent Application Publication No. US2009/0263965A1 and International Publication No. 2012/060428 are incorporated herein by reference.

Among the manganese compound gases (c1) to (c5), the amideaminoalkane-based manganese compound gas (c5) is preferred in some embodiments because it can form the metal manganese film 103 at a low temperature ranging from 250 to 300 degrees C. (e.g., 250 degrees C.).

When the cyclopentadienyl-based manganese compound gas (c1), e.g., a bis(ethylcyclopentadienyl) manganese gas (EtCp)₂Mn) is used, the formation temperature of the metal manganese film 103 is 400 to 450 degrees C. Further, when the amidinate-based manganese compound gas (c4) is used, the formation temperature of the metal manganese film 103 is 350 to 400 degrees C.

When forming the nitrogen-containing manganese film 102, the nitrogen-containing reaction gases (a1) to (a4) are used. Therefore, when forming the nitrogen-containing manganese film 102, even if any one of the manganese compound gases (c1) to (c5) is used, the nitrogen-containing manganese film 102 can be formed at a lower temperature than that of the metal manganese film 103.

When forming the nitrogen-containing manganese film 102 and the metal manganese film 103, it may be possible to use, instead of the CVD method, an ALD (Atomic Layer Deposition) method in which a manganese compound gas and a nitrogen-containing reaction gas or a reducing reaction gas are alternately supplied with a purge interposed. As the ALD method is used, surface adsorption and surface reaction occur. Thus, step coverage (coverage performance) is improved and a continuous film is easily formed even if a film thickness is thin. Film formation can be performed at a lower temperature.

In the case of using the ALD method, for example, the following processes 1 to 4 are repeated.
Process 1: adsorption of a manganese compound (Mn precursor) by a manganese compound gas (supply of a manganese compound gas)
Process 2: purge (vacuum purge or inert gas purge)
Process 3: decomposition of an adsorbed manganese compound (Mn precursor)
Process 4: purge (vacuum purge or inert gas purge)
In the ALD method, serial processes including the processes 1 to 4 are repeatedly performed.

In order to decompose the manganese compound (Mn precursor) adsorbed in the process 3, a nitrogen-containing reaction gas such as an NH₃ gas or the like is supplied to the surface of the silicon oxide film 101 onto which the manganese compound is adsorbed. Thus, the adsorbed manganese compound is decomposed to thereby leave the nitrogen-containing manganese on the surface of the silicon oxide film 101.

Alternatively, in order to decompose the manganese compound (Mn precursor) adsorbed in the process 3, a reducing reaction gas such as an H₂ gas or the like may be supplied to the surface of the nitrogen-containing manganese film 102 onto which the manganese compound is adsorbed. Thus, the adsorbed manganese compound is decomposed to thereby leave manganese on the surface of the nitrogen-containing manganese film 102.

When the nitrogen-containing manganese film 102 and the metal manganese film 103 are formed by the ALD method, it is preferred in some embodiments to form the metal manganese film 103 by the ALD method continuously by changing the nitrogen-containing reaction gas to a reducing reaction gas. That is to say, a manganese compound gas and a reducing reaction gas are alternately supplied with a purge interposed. When the nitrogen-containing manganese film 102 and the metal manganese film 103 are formed by a CVD method, the nitrogen-containing reaction gas may be changed to a reducing reaction gas during the processes. The timing for changing the nitrogen-containing reaction gas to the reducing reaction gas may be appropriately decided according to the required film thickness of the nitrogen-containing manganese film 102 and the metal manganese film 103.

As a decomposition method in the process 3, it may be possible to use decomposition by irradiation of energy or active species instead of the nitrogen-containing reaction gas such as an NH₃ gas or the like or the reducing reaction gas such as an H₂ gas or the like.

In such a case, an energy source employed in the decomposition using the irradiation of energy may include:
a particle beam (ions, atoms, molecules or the like accelerated by applying a bias voltage),
an electron beam (electrons accelerated by applying a bias voltage), and
an electromagnetic wave (light, a microwave, or the like)

Further, the active species employed in the decomposition using the irradiation of active species may include:
plasma (H plasma generated by remote plasma, or the like),
radicals (H radicals generated by a heating filament, NH₂ radicals, or the like), ions, and
electrons.

From the viewpoint of decomposing only an Mn precursor and avoiding damage affecting the underlayer, e.g., the silicon oxide film 101, it is preferred in some embodiments to use, among the energy sources, a method capable of preventing the silicon oxide film 101 from being exposed in a plasma generation region. In this regard, it is preferred to use a method using the remote plasma or the heating filament.

When selecting a decomposition method, it is preferable to properly select the decomposition method according to a kind of a film to be deposited or a film formation temperature. For example, when depositing the metal manganese film 103, the deposition using the reducing reaction gas or the deposition using the irradiation of energy or active species is selected. Also, a combination of the reducing reaction gas and the irradiation of energy or active species may be used. When depositing the nitrogen-containing manganese film 102, the decomposition using the nitrogen-containing reaction gas is selected. Also, a combination of the nitrogen-containing reaction gas and the irradiation of energy or active species may be used. The metal manganese film 103 or the nitrogen-containing manganese film 102 may be formed at a lower temperature by the decomposition using the irradiation of energy or active species.

Then, as illustrated in FIG. 1D, a copper film 105 is formed on the metal manganese film 103 by a PVD method, e.g., a sputtering method. Manganese existing in the metal manganese film 103 is diffused into the copper film 105 by heat generated when forming the copper film 105 or by annealing after formation of the copper film 105. As illustrated in FIG. 1E, the copper film 105 is changed to a manganese-diffused copper film 107. Moreover, oxygen or the like is diffused from the silicon oxide film 101 to the nitrogen-containing manganese film 102. Thus, a structure in which the silicon oxide film 101, the nitrogen-containing manganese film 106 including a manganese oxide disposed near an interface, the manganese-diffused copper film 107, and the manganese oxide film 108 formed by oxidation of manganese, which is diffused toward a surface of the copper film 107 and exposed on the surface of the copper film 107, are laminated on the silicon substrate 100 becomes a final structure.

In the first embodiment, the nitrogen-containing manganese film 102 of the manganese-containing film 104 serves as a barrier layer that restrains copper from being diffused from the copper film 105 into the silicon oxide film 101. The metal manganese film 103 of the manganese-containing film 104 serves as an adhesion layer to the copper film 105.

According to the method for forming a manganese-containing film according to the first embodiment, it is possible to obtain the following advantages.

(1) Since the copper film 105 is formed on the metal manganese film 103, the metals adjoin each other. Therefore, as compared with a case of using the manganese oxide film as the manganese-containing film and forming the copper film thereon, the adhesion between the copper film 105 and the manganese-containing film 104 is improved.

(2) Since an ammonia gas or a hydrazine gas is used as a reaction gas when forming the nitrogen-containing manganese film 102 on the silicon oxide film 101 as an underlayer film, it is possible to shorten an incubation time to thereby form the nitrogen-containing manganese film 102 as a continuous film. When the metal manganese film 103 is formed on the silicon oxide film 101 by a CVD method, the metal manganese film 103 may tend to become a film in which the metal manganese is scattered in an island shape due to the agglomeration of the metal manganese. However, since the nitrogen-containing manganese film 102 exists, it is possible to reliably form the manganese-containing film 104 as a continuous film.

(3) Since some manganese existing in the nitrogen-containing manganese film 102 is bonded to nitrogen, it is hard to be diffused into the copper film 105 as compared with the manganese existing in the metal manganese film 103. Therefore, as compared with a case that the manganese-containing film 104 is a monolayer structure of a metal manganese film, it is possible to reduce an amount of manganese diffused into the copper film 105. This makes it possible to suppress an increase in a resistance value of the copper film 107 attributable to a large amount of diffusion of manganese.

(4) Since an amideaminoalkane-based manganese compound gas is used as the manganese compound gas when forming the nitrogen-containing manganese film 102 and the metal manganese film 103, it is possible to, as mentioned above, form the nitrogen-containing manganese film 102 and the metal manganese film 103 at a low temperature.

### Second Embodiment

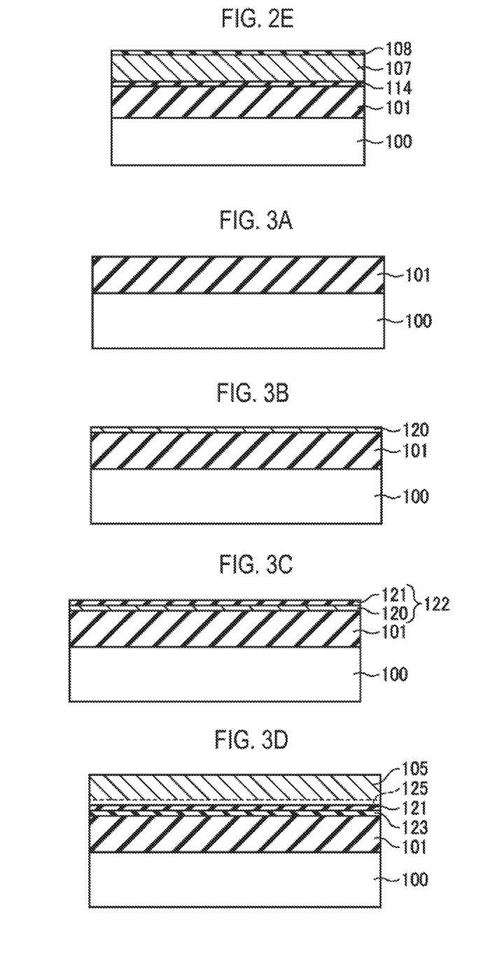

FIGS. 2A to 2E are sectional views illustrating one example of a method for forming a manganese-containing film according to a second embodiment of the present disclosure.

First, as illustrated in FIG. 2A, just like the first embodiment, for example, TEOS as a source gas is supplied to form a silicon oxide film 101 serving as an underlayer film on a silicon substrate 100 by a CVD method.

Then, as illustrated in FIG. 2B, a manganese compound gas is supplied onto the silicon oxide film 101 to thereby form a manganese oxide film 110 by an ALD method or a CVD method. The manganese oxide film 110 may be partially converted to silicate or may be a manganese silicate film. The manganese oxide film 110 can be formed by a method disclosed in Japanese Patent Application Publication No. 2010-242187. That is to say, the manganese oxide film 110 is formed at a temperature ranging from 100 degrees C. to 400 degrees C. using a cyclopentadienyl-based manganese compound such as, e.g., bis(alkyl cyclopentadienyl) manganese expressed by a chemical formula Mn(RC₅H₄)₂. In this regard, the R is an alkyl group denoted by —CₙH₂ₙ₊₁ (n is an integer equal to or greater than 0). At this time, oxygen for oxidizing manganese, and silicon and oxygen for converting manganese to silicate are supplied from the silicon oxide film 101. The oxygen supplied from the silicon oxide film 101 includes oxygen derived from moisture (physically adsorbed water and chemically adsorbed water) contained in the silicon oxide film 101.

Then, as illustrated in FIG. 2C, just like the metal manganese film 103 of the first embodiment, a manganese compound gas and a reducing reaction gas are supplied onto the manganese oxide film 110, and reacted with each other, thereby forming a metal manganese film 111 by an ALD method or a CVD method. Alternatively, a manganese compound gas may be supplied onto the manganese oxide film 110 and then thermally decomposed, thereby forming a metal manganese film 111 by an ALD method or a CVD method. Alternatively, a manganese compound gas may be supplied onto the manganese oxide film 110 and then decomposed through irradiation of energy or active species, thereby forming a metal manganese film 111 by an ALD method or a CVD method.

A manganese-containing film 112 of the present embodiment is formed with the manganese oxide film 110 and the metal manganese film 111.

In the second embodiment, the reducing reaction gas, the energy source or the active species described in respect of the first embodiment can be appropriately used as those used in forming the metal manganese film 111.

In the second embodiment, the manganese compound gas described in respect of the first embodiment can be appropriately used as that used in forming the manganese oxide film 110 and the metal manganese film 111. The kind of Mn precursor used in film formation can be appropriately selected according to reactivity with the oxygen supplied from the underlayer film (e.g., the oxygen derived from water), reactivity with the reducing reaction gas in a low temperature zone and thermal decomposition reactivity. If necessary, the kind of Mn precursor may be changed during film formation. For example, when the film formation temperature range is from 250 degrees C. to 400 degrees C., a manganese oxide film 110 is formed by a reaction of the cyclopentadienyl-based manganese compound and oxygen supplied from the silicon oxide film 101. Thereafter, a metal manganese film 111 can be formed by a thermal decomposition reaction of the amideaminoalkane-based manganese compound gas. In this way, the manganese-containing film 112 of the present embodiment can be formed by sequentially supplying different kinds of Mn precursors differing in a decomposition reaction characteristic, without changing the film formation temperature.

When forming the metal manganese film 111, an ALD method may be used instead of the CVD method. As the ALD method is used, surface adsorption and surface reaction occur. Thus, step coverage (coverage performance) is improved and a continuous film is easily formed even if a film thickness is small. Film formation can be performed at a lower temperature.

Then, as illustrated in FIG. 2D, a copper film 105 is formed on the metal manganese film 111 by a PVD method, e.g., a sputtering method. Just like the first embodiment, manganese existing in the metal manganese film 111 is diffused into the copper film 105 by the heat generated when forming the copper film 105 or by performing annealing after formation of the copper film 105. As illustrated in FIG. 2E, the copper film 105 is changed to a manganese-diffused copper film 107. Thus, the final structure becomes a structure in which the silicon oxide film 101, the manganese oxide (manganese silicate) film 114, the manganese-diffused copper film 107, and the manganese oxide film 108 formed by oxidation of manganese, which is diffused toward a surface of the copper film 107 and exposed on the surface of the copper film 107, are laminated on the silicon substrate 100.

In the second embodiment, the manganese oxide film 110 of the manganese-containing film 112 serves as a barrier layer that restrains diffusion of copper. The metal manganese film 111 of the manganese-containing film 112 serves as an adhesion layer to the copper film 105.

According to the method for forming a manganese-containing film according to the second embodiment, it is possible to obtain the following advantages.

(1) Since the copper film 105 is formed on the metal manganese film 111, just like the first embodiment, the adhesion between the copper film 105 and the manganese-containing film 112 can be improved.

(2) The manganese oxide film 110 formed on the silicon oxide film 101 using the cyclopentadienyl-based manganese compound gas becomes a continuous film in a lamellar structure. When the metal manganese film 111 is formed on the silicon oxide film 101 by a CVD method, the metal manganese film 111 may tend to become a film in which the metal manganese is scattered in an island shape due to the agglomeration of the metal manganese. However, since the manganese oxide film 110 exists, it is possible to reliably form the manganese-containing film 112 as a continuous film.

(3) Since manganese existing in the manganese oxide film 110 is bonded to oxygen, it is hard for the manganese to be diffused into the copper film 105 as compared with the manganese existing in the metal manganese film 111. Therefore, as compared with a monolayer structure of a metal manganese film, the manganese-containing film 112 can reduce an amount of the manganese diffused into the copper film 105. This makes it possible to suppress an increase in the resistance value of the copper film 107 attributable to a large amount of diffusion of manganese.

(4) Since an amideaminoalkane-based manganese compound gas is used as the manganese compound gas when forming the metal manganese film 111, it is possible to, as mentioned above, form the metal manganese film 111 at a relatively low temperature.

### Third Embodiment

FIGS. 3A to 3D are sectional views illustrating one example of a method for forming a manganese-containing film according to a third embodiment of the present disclosure.

First, as illustrated in FIG. 3A, just like the first embodiment, for example, TEOS as a source gas is supplied to form a silicon oxide film 101 on a silicon substrate 100 by a CVD method.

Then, as illustrated in FIG. 3B, a manganese compound gas and a reducing reaction gas are supplied onto the silicon oxide film 101, and reacted with each other, thereby forming a metal manganese film 120 by an ALD method or a CVD method. From the viewpoint of forming a continuous film, the ALD method is used in some embodiments. That is to say, when the metal manganese film 120 is formed on the silicon oxide film 101 by the CVD method, the metal manganese film 120 tends to become a film in which the metal manganese is scattered in an island shape due to the agglomeration of metal manganese. However, by using the ALD method, it is possible to form the metal manganese film 120 into a continuous film. Alternatively, a manganese compound gas is supplied onto the silicon oxide film 101 and then subjected to a decomposition reaction through the irradiation of energy or active species, thereby forming a metal manganese film 120 by an ALD method or a CVD method.

Then, as illustrated in FIG. 3C, a nitrogen-containing manganese film 121 is formed on the metal manganese film 120 by an ALD method or a CVD method using a manganese compound gas and a nitrogen-containing reaction gas. When the metal manganese film 120 is formed by the ALD method, the reducing reaction gas in some embodiments is changed to a nitrogen-containing reaction gas and then a nitrogen-containing manganese film is formed by the ALD method continuously. That is to say, the manganese compound gas and the nitrogen-containing reaction gas are alternately supplied with a purge interposed.

A manganese-containing film 122 of the present embodiment is formed by the metal manganese film 120 and the nitrogen-containing manganese film 121.

In the third embodiment, the reducing reaction gas described with respect of the first embodiment can be appropriately used as in the reducing reaction gas when forming the metal manganese film 120.

In the third embodiment, the nitrogen-containing reaction gas described with respect of the first embodiment can be appropriately used as the nitrogen containing reaction gas when forming the nitrogen-containing manganese film 121.

In the third embodiment, the manganese compound gas described with respect of the first embodiment can be appropriately used as the manganese compound gas when forming the metal manganese film 120 and the nitrogen-containing manganese film 121.

Then, as illustrated in FIG. 3D, a copper film 105 is formed on the manganese-containing film 122 by a PVD method, e.g., a sputtering method. By the heat generated when forming the copper film 105 or by performing annealing after formation of the copper film, the final structure becomes a structure in which the silicon oxide film 101, the manganese silicate film 123, the nitrogen-containing manganese film 121, and the copper film 125 formed by slightly diffusing manganese into copper, are laminated on the silicon substrate 100. In the present embodiment, the nitrogen-containing manganese film 121 and the annealed manganese silicate film 123 serve as barrier layers that restrain diffusion of copper. The nitrogen-containing manganese film 121 serves as an adhesion layer to the copper film 125.

As described in the first and second embodiments, manganese is easily diffused into the copper film. However, in the third embodiment, unlike the first and second embodiments, a film making contact with the copper film 105 is not the metal manganese film but the nitrogen-containing manganese film 121. As such, an amount of manganese capable of diffusing into the copper film 105 is smaller than those of the first and second embodiments in which the metal manganese film makes contact with the copper film 105. Thus, the manganese oxide film, which is formed according to the first and second embodiments, is not formed or is hardly formed on the surface of the copper film 105.

According to the method for forming a manganese-containing film according to the third embodiment, it is possible to obtain the following advantages.

(1) Since the copper film 105 is formed on the nitrogen-containing manganese film 121, the adhesion between the copper film 105 and the manganese-containing film 122 is improved as compared with a case of using a manganese oxide film as the manganese-containing film and forming the copper film 105 on the manganese oxide film.

(2) The metal manganese film 120 is formed on the silicon oxide film 101 by an ALD method. Therefore, unlike a case of forming a metal manganese film by a CVD method, surface adsorption and surface reaction occur. Thus, step coverage (coverage performance) is improved and a continuous film is easily formed even if a film thickness is small. This makes it possible to form the manganese-containing film 122 into a continuous film extending in a lamella structure.

(3) Since the copper film 105 is formed on the nitrogen-containing manganese film 121 in which some of the manganese is bonded to nitrogen, the diffusion of manganese into the copper film 105 is suppressed. This makes it possible to suppress an increase in a resistance value of the copper film 125 attributable to the diffusion of manganese.

(4) Since an amideaminoalkane-based manganese compound gas is used as the manganese compound gas when forming the metal manganese film 120 and the nitrogen-containing manganese film 121, it is possible to form the metal manganese film 120 and the nitrogen-containing manganese film 121 at a relatively low temperature.

### Fourth Embodiment

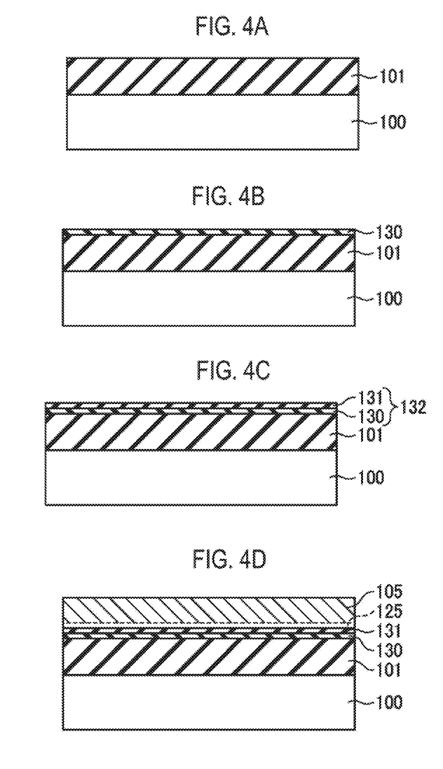

FIGS. 4A to 4D are sectional views illustrating one example of a method for forming a manganese-containing film according to a fourth embodiment of the present disclosure.

First, as illustrated in FIG. 4A, just like the first embodiment, for example, TEOS as a source gas is supplied to form a silicon oxide film 101 serving as an underlayer film on a silicon substrate 100 by a CVD method.

Then, as illustrated in FIG. 4B, a manganese compound gas is supplied onto the silicon oxide film 101 to form a manganese oxide film 130 by an ALD method or a CVD method. The manganese oxide film 130 may be partially converted to silicate. The manganese oxide film 130 is formed using a Mn precursor having a property reactive with water. Examples of the Mn precursor having a property reactive with water includes an amideaminoalkane-based manganese compound denoted by a chemical formula Mn(R¹N—Z—NR²₂)₂, where the R¹ and R² are alkyl groups denoted by —CₙH₂ₙ₊₁ (n is an integer equal to or greater than 0) and the Z is an alkylene group denoted by —CₙH₂ₙ— (n is an integer equal to or greater than 0). In the present embodiment, the film is formed by using, for example, a bis (N,N′-1-alkylamide-2-dialkylaminoalkane) manganese gas as the manganese compound gas at a temperature ranging from 100 degrees C. to 250 degrees C. (e.g., 200 degrees C.). At this time, oxygen for oxidizing manganese, and silicon and oxygen for converting manganese to silicate are supplied from the silicon oxide film 101. The oxygen supplied from the silicon oxide film 101 includes oxygen derived from moisture (physically adsorbed water and chemically adsorbed water) contained in the silicon oxide film 101.

In the present embodiment, the manganese oxide film 130 is formed using the oxygen supplied from an underlayer. For that reason, during the formation of the manganese oxide film 130, the kind of Mn precursor is not changed from a type having a property reactive with water to a type having a property not reactive with water.

Then, as illustrated in FIG. 4C, a manganese compound gas and a nitrogen-containing reaction gas are supplied onto the manganese oxide film 130 and then reacted with each other, thereby forming a nitrogen-containing manganese film 131 by an ALD method or a CVD method.

A manganese-containing film 132 of the present embodiment is formed by the manganese oxide film 130 and the nitrogen-containing manganese film 131.

In the fourth embodiment, the manganese compound gas described with respect to the first embodiment can be appropriately used as that used in forming the manganese oxide film 130 and the nitrogen-containing manganese film 131.

Particularly, a manganese compound gas having a property reactive with water among the manganese compound gases belonging to the following gases may be selected in some embodiments

(c1) a cyclopentadienyl-based manganese compound gas (denoted by a chemical formula Mn(RC₅H₄)₂),

(c2) a carbonyl-based manganese compound gas,

(c3) a beta-diketone-based manganese compound gas,

(c4) an amidinate-based manganese compound gas (denoted by a chemical formula Mn(R¹N—CR³—NR²)₂), and

(c5) an amideaminoalkane-based manganese compound gas (denoted by a chemical formula Mn(R¹N—Z—NR²₂)₂), which are described in the first embodiment, as the manganese compound gas used in forming the manganese oxide film 130.

In the fourth embodiment, the nitrogen-containing reaction gas described with respect to the first embodiment can be appropriately used as that used in forming the nitrogen-containing manganese film 131.

Then, as illustrated in FIG. 4D, a copper film 105 is formed on the manganese-containing film 132 by a PVD method. e.g., a sputtering method. By the heat generated when forming the copper film 105 or by performing annealing after formation of the copper film, the final structure becomes a structure in which the silicon oxide film 101, the manganese oxide film 130, the nitrogen-containing manganese film 131, and the copper film 125 formed by slightly diffusing manganese into copper, are laminated on the silicon substrate 100. In the present embodiment, the manganese oxide film 130 and the nitrogen-containing manganese film 131 serve as barrier layers that restrain diffusion of copper. The nitrogen-containing manganese film 131 serves as an adhesion layer to the copper film 125.

In the fourth embodiment, just like the third embodiment, the nitrogen-containing manganese film 131 makes contact with the copper film 105. Thus, just like the third embodiment, the manganese oxide film, which is formed according to the first and second embodiments, is not formed or hardly formed on the surface of the copper film 125.

According to the method for forming a manganese-containing film according to the fourth embodiment, it is possible to obtain the following advantages.

(1) The manganese oxide film 130 formed on the silicon oxide film 101 using the amideaminoalkane-based manganese compound gas becomes a continuous film extending in a lamella structure. Since the manganese oxide film 130 exists, it is possible to reliably form the manganese-containing film 132 as a continuous film.

(2) Since the copper film 105 is formed on the nitrogen-containing manganese film 131, the adhesion between the copper film 105 and the manganese-containing film 132 is improved as compared with a case where a manganese oxide film is used as the manganese-containing film and the copper film 105 is formed on the manganese oxide film.

(3) Since the copper film 105 is formed on the nitrogen-containing manganese film 131 in which some of the manganese is bonded to nitrogen, the diffusion of manganese into the copper film 105 is suppressed. This makes it possible to suppress an increase in a resistance value of the copper film 125 attributable to the diffusion of manganese.

(4) Since an amideaminoalkane-based manganese compound gas is used as the manganese compound gas when forming the manganese oxide film 130 and the nitrogen-containing manganese film 131, it is possible to form the manganese oxide film 130 and the nitrogen-containing manganese film 131 at a relatively low temperature.

### <Example of a Semiconductor Device Manufacturing Method>

Next, an example of applying the methods for forming the manganese-containing film according to the first to fourth embodiments to a barrier layer of a semiconductor integrated circuit device will be described.

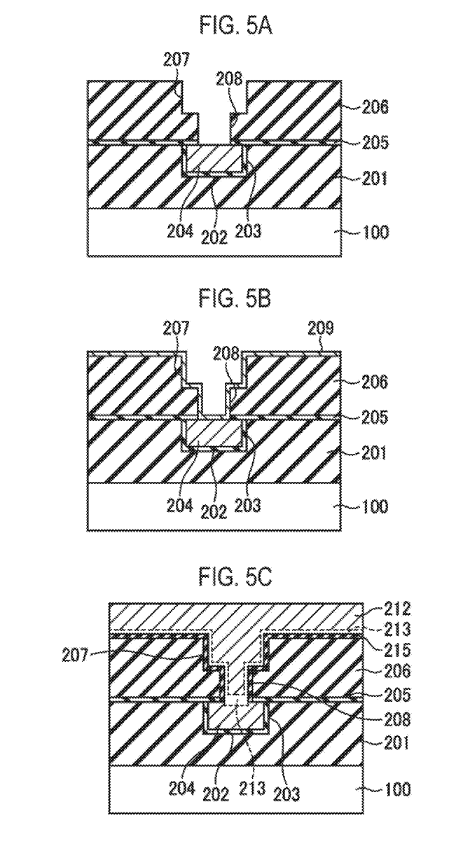

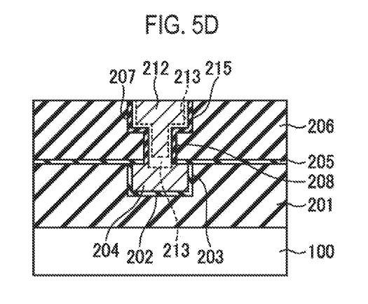

FIGS. 5A to 5D are sectional views illustrating one example of a semiconductor device manufacturing method.

As illustrated in FIG. 5A, a silicon oxide film 201 as a first inter-layer insulation film is formed on a silicon substrate 100. A groove 202 for burying a wire is formed in the silicon oxide film 201. A first copper wire 204 is buried within the groove 202 by interposing a barrier layer 203. A cap film 205 is formed on a top surface of the silicon oxide film 201 and a top surface of the first copper wire 204. A silicon oxide film 206 as a second inter-layer insulation film is formed on the cap film 205. A groove 207 for burying a wire is formed in the silicon oxide film 206. A via-hole 208 leading to the first copper wire 204 is formed in a bottom portion of the groove 207. A surface of the first copper wire 204 is exposed in a bottom of the via-hole 208. In this regard, the silicon oxide films 201 and 206 are not limited to SiO₂. It may be possible to use a Si-containing insulation film (a low-k film) lower relative permittivity than SiO₂, such as SiOC, SiOCH or the like. It may also be possible to use a porous low-k film having pores. Furthermore, the barrier layer 203 may be formed of metal tantalum, tantalum nitride, metal titanium or titanium nitride as well as a manganese-containing film such as manganese oxide, manganese silicate or the like. Moreover, the cap film 205 may be formed of SiC, SiN or SiCN as well as a manganese-containing film such as manganese oxide, manganese silicate or the like. A process for making the surroundings of a transistor, namely the FEOL (Front End of Line), is omitted herein.

Then, as illustrated in FIG. SB, a manganese-containing film 209 is formed on the silicon oxide film 206 and on a portion of the first copper wire 204, which is exposed in the bottom of the via-hole 208, by one of the methods according to the first to fourth embodiments.

Then, as illustrated in FIG. 5C, a copper film 212 is formed on the manganese-containing film 209 by a PVD method, e.g., a sputtering method. The copper film 212 may be formed through two processes of forming a copper seed layer by a sputtering method and depositing a copper film by an electrolytic plating method. Manganese existing in the portion of the manganese-containing film 209 formed on the silicon oxide film 206 is diffused into the copper film 212 by heat generated in forming the copper film 212 or annealing after formation of the copper film 212, thereby forming a diffusion layer 213 at a portion or the entire copper film 212. A film 215 including a nitrogen-containing manganese film, a manganese oxide film or a manganese silicate film is formed at a side of the silicon oxide film 206, so that manganese existing in a portion of the manganese-containing film 209, which is formed on the first copper wire 204, is diffused into the copper film 212 and the first copper wire 204. Thus, the diffusion layer 213 is formed at a portion or the entire copper film 212 and the first copper wire 204. In such a case, the manganese-containing film 209 formed on the first copper wire 204 includes a metal manganese film and partially includes manganese oxide even if the manganese oxide is contained therein. Therefore, the manganese oxide as an insulation film does not exist in the bottom of the via-hole 208, or only a small amount of the manganese oxide remains in the bottom of the via-hole 208. Depending on the diffusion amount of manganese, there may be a case that a manganese oxide film is formed on the surface of the copper film 212.

Then, as illustrated in FIG. 5D, the copper film 212, the diffusion layer 213 and the film 215 are removed by, e.g., polishing, so that only the copper film 212 buried within the groove 207 and the via-hole 208 is left. Thus, a second copper wire is formed.

According to the semiconductor device manufacturing method described above, it is possible to obtain the same advantages as obtained in the first to fourth embodiments. Since a manganese oxide does not exist or only a small amount of the manganese oxide exists on a contact surface of the copper film 212 and the first copper wire 204, it is possible to reduce the contact resistance of the copper film 212 and the first copper wire 204.

### <Film-Forming System>

Next, a film-forming system which can be used in forming the manganese-containing film of the first to fourth embodiments will be described.

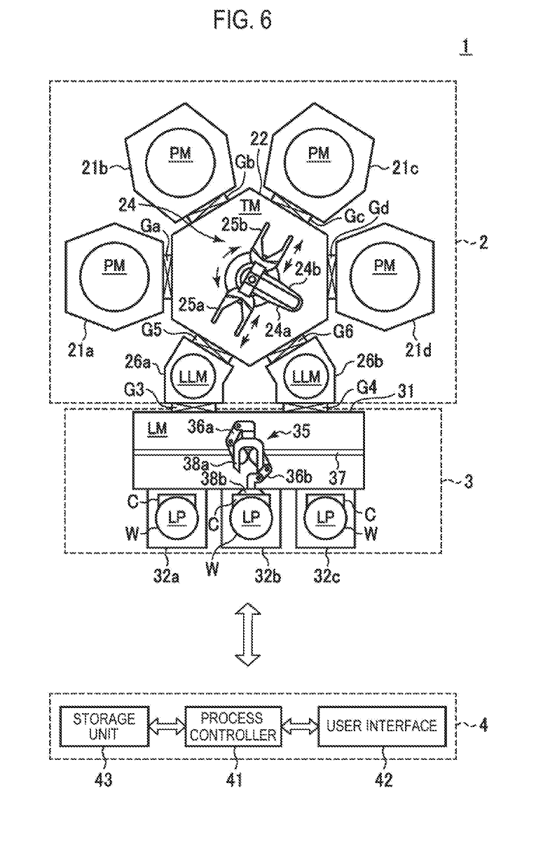

FIG. 6 is a plane view schematically illustrating one example of the film-forming system. This example is used as one example of the film-forming system in forming a semiconductor device, and illustrates a film-forming system configured to perform a film-forming process with respect to a silicon wafer (hereinafter referred to as a wafer) as a substrate. However, the present disclosure is not limited to the formation of a manganese film on a wafer.

### (Overall Configuration)

As illustrated in FIG. 6, the film-forming system 1 includes a processing part 2 configured to perform processes with respect to a wafer W, a carry-in/carry-out part 3 configured to carry the wafer W into and out of the processing part 2, and a control part 4 configured to control the film-forming system 1. The film-forming system 1 according to the present example is a semiconductor manufacturing apparatus of a cluster-tool type (multi-chamber type).

In the present example, the processing part 2 includes four process chambers (PM: process modules) 21a to 21d configured to carry out processes with respect to the wafer W. Each of the process chambers 21a to 21d is configured such that an inside thereof can be depressurized to a predetermined vacuum degree. In the process chamber 21a, pretreatments are performed for the wafer W such as degassing through heating, removing natural copper oxide through hydrogen annealing, and reforming a surface of an underlayer through the irradiation of plasma or ions (specifically, irradiating plasma or ions on a porous low-k film to make pores small to prevent a manganese compound gas from being infiltrated into a low-k film). In the process chamber 21b, there is performed a formation process of a manganese-containing film as a film-forming process on the wafer W. In the process chamber 21c, there is performed a PVD film-forming process, e.g., a sputtering process, of copper or copper alloy. In the process chamber 21d, there is performed a heating process, e.g., annealing with a small amount of oxygen, for forming silicate and diffusing manganese. The process chambers 21a to 21d are connected to one transfer chamber (TM: transfer module) 22 through gate valves Ga to Gd.

The carry-in/carry-out part 3 includes a carry-in/carry-out chamber (LM: loader module) 31. The internal pressure of the carry-in/carry-out chamber 31 can be regulated to an atmospheric pressure or a substantially atmospheric pressure, e.g., a slightly higher positive pressure than the external atmospheric pressure. In the present example, the plane-view shape of the carry-in/carry-out chamber 31 is a rectangular shape having a long side and a short side orthogonal to the long side when seen in a plane view. The long side of the rectangle adjoins the processing part 2. The carry-in/carry-out chamber 31 includes load ports (LP) on which workpiece substrate carriers C accommodating wafers W are installed. In the present example, three load ports 32a, 32b and 32c are installed along the long side of the carry-in/carry-out chamber 31, which faces the processing part 2. While it is described that the number of the load ports is three in the present example, the present disclosure is not limited thereto. The number of the load ports is arbitrary. A shutter not shown is installed in each of the load ports 32a, 32b and 32c. If a carrier C storing wafers W or an empty carrier C is mounted to each of the load ports 32a, 32b and 32c, the shutter not shown is opened. Thus, the inside of the carrier C and the inside of the carry-in/carry-out chamber 31 communicate with each other while preventing infiltration of the ambient air.

Load lock chambers (LLM: load lock modules), namely two load lock chambers 26a and 26b in the present example, are installed between the processing part 2 and the carry-in/carry-out part 3. The load lock chambers 26a and 26b are configured such that the internal pressure of each of the load lock chambers 26a and 26b can be converted to a predetermined vacuum degree and an atmospheric pressure or a substantially atmospheric pressure. The respective load lock chambers 26a and 26b are connected to one side of the carry-in/carry-out chamber 31, which is opposite the side on which the load ports 32a. 32b and 32c are installed, through gate valves G3 and G4. The respective load lock chambers 26a and 26b are connected to two sides of the transfer chamber 22 except four sides connected with the process chambers 21a to 21d, through gate valves G5 and G6. The load lock chambers 26a and 26b communicate with the carry-in/carry-out chamber 31 by opening the corresponding gate valve G3 or G4 and are disconnected from the carry-in/carry-out chamber 31 by closing the corresponding gate valve G3 or G4. Furthermore, the load lock chambers 26a and 26b communicate with the transfer chamber 22 by opening the corresponding gate valve G5 or G6 and are disconnected from the transfer chamber 22 by closing the corresponding gate valve G5 or G6.

A carry-in/carry-out mechanism 35 is installed within the carry-in/carry-out chamber 31. The carry-in/carry-out mechanism 35 carries a wafer W into or out of the workpiece substrate carriers C. Moreover, the carry-in/carry-out mechanism 35 carries a wafer W into or out of the load lock chambers 26a and 26b. The carry-in/carry-out mechanism 35 is provided with, e.g., two multi-joint arms 36a and 36b and is configured to run over a rail 37 extending in a longitudinal direction of the carry-in/carry-out chamber 31. Hands 38a and 38b are installed at tips of the multi-joint arms 36a and 36b. The carry-in/carry-out procedure of the wafer W by being placed on the hand 38a or 38b is performed as described above.

The transfer chamber 22 is configured to maintain vacuum with, for example, a vacuum container. A transfer mechanism 24 configured to transfer the wafer W between the process chambers 21a to 21d and the load lock chambers 26a and 26b is installed within the transfer chamber 22. The wafer W is transferred in such a state that it is isolated from the atmospheric air. The transfer mechanism 24 is disposed substantially at the center of the transfer chamber 22. The transfer mechanism 24 is provided with, e.g., a plurality of rotatable/extendable/retractable transfer arms. In the present example, the transfer mechanism 24 includes, e.g., two transfer arms 24a and 24b. Holders 25a and 25b are installed at tips of the transfer arms 24a and 24b. The wafer W is held by the holder 25a or 25b and is transferred between the process chambers 21a to 21d and the load lock chambers 26a and 26b as mentioned above.

The control part 4 includes a process controller 41, a user interface 42 and a storage unit 43.

The process controller 41 is formed of a microprocessor (computer).

The user interface 42 includes a keyboard through which an operator performs a command input operation or other operations to manage the processing system 1, a display configured to visually display an operation situation of the processing system 1, and so forth.

The storage unit 43 stores a control program for realizing the processes carried out in the processing system 1 under the control of the process controller 41, various types of data, and recipes for causing the processing system 1 to execute processes according to processing conditions. The recipes are stored in a storage medium of the storage unit 43. The storage medium, which is computer-readable, may be, e.g., a hard disk or a portable storage medium such as a CD-ROM, a DVD, a flash memory or the like. Alternatively, recipes may be appropriately transmitted from other devices via. e.g., a dedicated line. In response to an instruction from the user interface 42, an arbitrary recipe is called out from the storage unit 43 and is executed by the process controller 41, whereby the processes for the wafer W are performed under the control of the process controller 41.

### (Manganese-Containing Film Forming Apparatus)

Next, one example of a manganese-containing film forming apparatus will be described. In the present example, the manganese-containing film forming apparatus is used in the process chamber 21b.

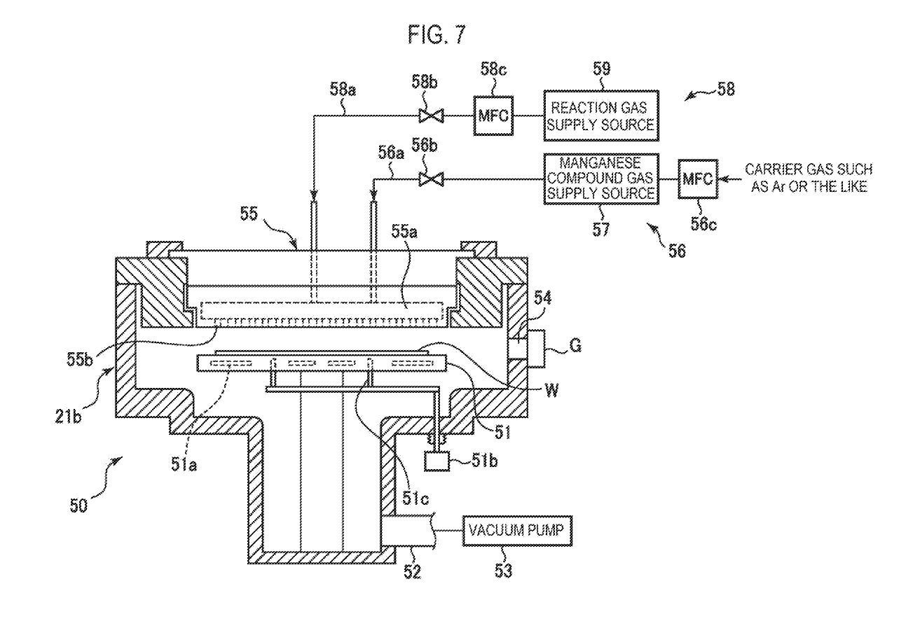

FIG. 7 is a sectional view schematically illustrating one example of a manganese-containing film CVD apparatus.

As illustrated in FIG. 7, the manganese-containing film CVD apparatus 50 includes a process chamber 21b. A mounting table 51 for horizontally supporting a wafer W is installed within the process chamber 21b. A heater 51a serving as a wafer temperature adjusting means is installed within the process chamber 21b. Three elevating pins 51c (only two of which are shown for the sake of convenience) capable of being moved up and down by an elevator mechanism 51b are installed in the mounting table 51. The wafer W is delivered between a wafer transfer means not shown and the mounting table 51 through the elevating pins 51c.

One end portion of an exhaust pipe 52 is connected to a bottom portion of the process chamber 21b. A vacuum pump 53 is connected to the other end portion of the exhaust pipe 52. A transfer gate 54 opened and closed by a gate valve G is formed in a sidewall of the process chamber 21b.

A gas shower head 55 facing the mounting table 51 is installed in a ceiling portion of the process chamber 21b. The gas shower head 55 includes a gas chamber 55a. A gas supplied to the gas chamber 55a is supplied from a plurality of gas injection holes 55b into the process chamber 21b.

A manganese compound gas supply piping system 56 for introducing a manganese compound gas into the gas chamber 55a is connected to the gas shower head 55. The manganese compound gas supply piping system 56 includes a gas supply path 56a. A valve 56b, a manganese compound gas supply source 57 and a mass flow controller 56c are connected to an upstream side of the gas supply path 56a. For example, a bis(amideaminoalkane) manganese compound gas is supplied from the manganese compound gas supply source 57 by a bubbling method.

A reaction gas supply piping system 58 for introducing a reaction gas into the gas chamber 55a is connected to the gas shower head 55. The reaction gas supply piping system 58 includes a gas supply path 581. A reaction gas supply source 59 is connected to the upstream side of the gas supply path 58a through a valve 58b and a mass flow controller 58c. For example, a hydrogen gas, an ammonia gas, and so forth, are supplied from the reaction gas supply source 59. In the present embodiment, a manganese compound gas and a reaction gas are mixed within the gas chamber 55a of the gas shower head 55 and are then supplied from the gas injection holes 55b into the process chamber 21b (pre-mix method). However, the present disclosure is not limited thereto. A gas chamber only for a manganese compound gas and a gas chamber only for a reaction gas may be independently installed in the gas shower head 55, so that a manganese compound gas and a reaction gas can be individually supplied into the process chamber 21b (post-mix method).

### (Example of Pretreatment Conditions for the Wafer W)

### <Degassing Process by Heating>

A degassing process by heating can be performed, e.g., in the process chamber 21a, before a manganese-containing film is formed in the process chamber 21b. Examples of the process conditions are as follows.

Wafer temperature: 250 to 400 degrees C.

Process Pressure: 13 to 2670 Pa

Process Atmosphere: an atmosphere of an inert gas such as N₂, Ar, He or the like

Process time: 30 to 300 seconds

More suitable process conditions are as follows.

Wafer temperature: 300 degrees C.

Process pressure: 1330 Pa

Process atmosphere: an atmosphere of an Ar gas

Process time: 120 seconds

By virtue of the degassing process, surplus moisture or volatile components contained in, e.g., the silicon oxide film 101, can be removed from the silicon oxide film 101. This makes it possible to form a high-quality manganese-containing film in the process chamber 21b. In addition, the controllability of a film thickness is improved.

### <Removal Process of a Natural Copper Oxide by Hydrogen Annealing>

A removal process of a natural copper oxide by hydrogen annealing is applied, e.g., when a copper film exists in a portion of an underlayer as the example described with reference to FIGS. 5A to 5D. The removal process of a natural copper oxide by hydrogen annealing can be performed, e.g., in the process chamber 21a, before a manganese-containing film is formed in the process chamber 21b. Examples of the process conditions are as follows.

Wafer temperature: 250 to 400 degrees C.

Process pressure: 13 to 2670 Pa

Process atmosphere: an H₂ gas atmosphere (to which an inert gas such as N₂, Ar, He or the like may be added), where an H₂ concentration is 1 to 100 volume %

Process time: 30 to 300 seconds

More suitable process conditions are as follows.

Wafer temperature: 300 degrees C.

Process pressure: 1330 Pa

Process atmosphere: an atmosphere of 3% of H₂ gas and 97% of Ar gas

Process time: 120 seconds

By virtue of the hydrogen annealing process, a natural copper oxide can be reduced and removed from, e.g., the surface of a copper film exposed in the underlayer. This makes it possible to form a high-quality manganese-containing film in the process chamber 21b. This also makes it possible to reduce the resistance of a copper wire in a via-hole portion.

<Reforming Process of an Underlayer Surface Using Plasma and/or Ion Irradiation>

It is preferred in some embodiments that the reforming process of an underlayer surface is applied when, e.g., a low-k film exists in the underlayer. The reforming process of an underlayer surface can be performed, e.g., in the process chamber 21a, before a manganese-containing film is formed in the process chamber 21b. Examples of the processing conditions when hydrogen radicals are used as reactive species are as follows.

Generation of radicals/ions: Atomic hydrogen is generated by remote plasma, plasma or a heating filament and is irradiated on a wafer W.

Input power: 1 to 5 kW (more preferably 1.5 kW to 3 kW)

Wafer Temperature: room temperature (25 degrees C.) to 450 degrees C. (more preferably 200 to 400 degrees C.)

Process pressure: 10 to 500 Pa (more preferably 20 to 100 Pa)

Process atmosphere: an atmosphere of 1 to 20% of H₂ gas+99 to 80% of Ar gas

Process time: 5 to 300 seconds (more preferably 10 to 100 seconds)

The most suitable conditions in the example of remote plasma are as follows.

Input power: 2.5 kW

Wafer temperature: 300 degrees C.

Process pressure: 40 Pa

Process atmosphere: 10% of H₂ gas+90% of Ar gas

Process time: 60 seconds

By virtue of this reforming process, a high-quality manganese-containing film can be formed on, e.g., the underlayer, in the process chamber 21b.

At least one of the degassing process by heating, the removal process of a natural copper oxide by hydrogen annealing, and the reforming process of an underlayer surface by the irradiation of plasma or ions, can be carried out prior to forming a manganese-containing film.

### (Detailed Example of the Reforming Process of the Underlayer Surface)

Next, a detailed example of the reforming process of the underlayer surface which can be desirably applied when a low-k film, e.g., a SiOC film or a SiOCH film, exists on the underlayer.

### <Reforming Process of a Underlayer Surface Using Plasma Irradiation>

As mentioned above, the reforming process of an underlayer surface is performed, e.g., in the process chamber 21a, before a manganese-containing film is formed in the process chamber 21b. In the process chamber 21a, plasma is generated, and, for example, the silicon oxide film 206, which is a second inter-layer insulation film illustrated in FIG. 5A, is exposed to the generated plasma. Alternatively, the silicon oxide film 206 is exposed to radical species derived from the plasma. Thus, the surface of the silicon oxide film 206 is reformed. In this reformation, the surface of the silicon oxide film 206 is subjected to the following processes.

Removal of carbon (C)

Densification (density increase)

Surface hydrophilization

Pore diameter reduction

During the reforming process using the plasma irradiation, in order to suppress a side effect such as damage or the like which may affect the silicon oxide film 206, careful attention should be made not to perform excessive irradiation.

When generating plasma, it is possible to use a gas which contains hydrogen (H), carbon (C), nitrogen (N) or oxygen (O). Examples of the gas containing hydrogen, carbon, nitrogen or oxygen include:

a H₂ gas,

a CO gas,

a CO₂ gas,

a CH₄ gas,

a N₂ gas,

a NH₃ gas,

a H₂O gas,

an O₂ gas,

an O₃ gas,

a NO gas,

a N₂O gas, and

a NO₂ gas.

Plasma may be generated using one of the aforementioned gases or the combination thereof. In order to facilitate the ignition of plasma, a rare gas such as He, Ar or the like may be added. In the aforementioned example, the process atmosphere is an atmosphere of 1 to 20% of H₂ gas and 99 to 80% of Ar gas.

In general, the low-k material (e.g., SiOC) constituting an inter-layer insulation film is formed of an organic material such as trimethylsilane or the like. Thus, the inter-layer insulation film formed using an organic material contains alkyl groups such as a methyl group (—CH₃) and the like. For that reason, a specified amount of carbon (C) is contained in the inter-layer insulation film. The surface of the inter-layer insulation film is reformed by exposing the same to plasma or ions. Thus, the majority of carbon is removed from the surface of the inter-layer insulation film. Consequently, the composition of the surface of the inter-layer insulation film becomes close to SiO₂ from SIOC. As a result, carbon is removed from the surface of the inter-layer insulation film formed by an organic material, whereby a densified (high-density) SiO₂-like reformed layer is formed.

According to the aforementioned formation method, the majority of the surface of the inter-layer insulation film is terminated with a methyl group (—CH₃). Thus, the surface of the inter-layer insulation film becomes a hydrophobic surface. By performing the aforementioned reforming process, the methyl group is cut into an —OH group or a Si—O—Si bond. That is to say, the aforementioned reforming process has an aspect for hydrophilic treatment that hydrophilizes the surface of the inter-layer insulation film (The surface of the inter-layer insulation film is reformed from a hydrophobic surface to a hydrophilic surface by the reforming process). Since a reformed layer of hydrophilicity is formed on the surface of the inter-layer insulation film, it becomes easy to efficiently form (deposit) a manganese-containing film on the surface of the inter-layer insulation film.

When the inter-layer insulation film is a porous low-k film, if the aforementioned reforming process is performed, the pores of the surface of the inter-layer insulation film are reduced in diameter and/or blocked. That is to say, a non-porous reformed layer is formed on the surface of the inter-layer insulation film. This reformed layer serves as a pore seal of the inter-layer insulation film. As a result, when forming a manganese-containing film, a Mn precursor for forming the manganese-containing film is infiltrated into the inter-layer insulation film. This makes it possible to suppress an increase in the relative permittivity of the inter-layer insulation film.

The plasma process time for the reforming process may be about several seconds (e.g., 1 to 300 seconds). The process pressure and the high-frequency power used in the plasma process are not particularly limited. Practically, the process pressure is set to fall within a range of 10⁻¹ to 10⁵ Pa and the input power of the high-frequency power is set to fall within a range of 10¹ to 10⁴ Watt. In the aforementioned embodiment, the process time is 5 to 300 seconds, the process pressure is 10 to 500 Pa and the input power is 1 to 5 kW.

In the case of a hydrogen-containing gas, an oxygen-containing gas or the combination thereof is used during the plasma process for the reforming process, there is provided an advantage in that it is possible to accelerate formation of an —OH group on the surface of the inter-layer insulation film. If the —OH group is formed on the surface of the inter-layer insulation film, it becomes easy to efficiently form (deposit) a manganese-containing film on the surface of the inter-layer insulation film. Examples of the hydrogen-containing gas or the oxygen-containing gas include:

a H₂ gas,

a CO gas,

a CO₂ gas,

a CH₄ gas,

a NH₃ gas,

a H₂O gas,

an O₂ gas,

an O₃ gas,

a NO gas, and

a N₂O gas.

In order to enhance the effect of the plasma process for the reforming process, the surface of the inter-layer insulation film may be plasma-processed while heating the wafer W to a temperature range of 100 to 350 degrees C.

As a means for generating the plasma, it is possible to use:

a capacitively coupled plasma (CCP) generation means,

an inductively coupled plasma (ICP) generation means,

a helicon wave plasma (HWP) generation means,

a microwave-excited surface wave plasma (SWP) generation means (including RLSA™ microwave plasma and SPA (Slot Plane Antenna) plasma),

an electron cyclotron resonance plasma (ECP) generation means, and

a remote plasma generation means using the aforementioned generation means.

### <Underlayer Surface Reforming Process Using Ultraviolet Irradiation>

The surface of the inter-layer insulation film can be reformed by many different methods other than the method of exposing the surface of the inter-layer insulation film to plasma. In order to reform (primarily hydrophilize, in this example) the surface of the inter-layer insulation film, ultraviolet rays may be irradiated on the surface of the inter-layer insulation film while, for example, heating the wafer W to a temperature of 100 to 350 degrees C. under an oxygen atmosphere (e.g., under an atmosphere of oxygen-containing gas which contains ozone (O₃) or oxygen (O₂). When irradiating the ultraviolet rays, it is possible to use a low-pressure mercury lamp (wavelength: 185 to 254 nm) or a Xe excimer lamp (wavelength: 172 nm). In some embodiments short-wavelength ultraviolet rays (wavelength: 240 nm or less) are used.

### <Underlayer Surface Reforming Process Using GCIB Irradiation>

A gas cluster ion beam (GCIB) may be irradiated on the surface of the inter-layer insulation film. This makes it possible to reform the surface of the inter-layer insulation film. Examples of a gas for generating gas cluster ions include:

an O₂ gas,

a N₂ gas,

a H₂ gas,

a CH₄ gas,

an Ar gas, and

a He gas.

### <Underlayer Surface Reforming Process Using Visible Light Irradiation>

Visible light having a wavelength of 425 nm may be irradiated on the surface of the inter-layer insulation film. The visible light (purple color) having a wavelength of 425 nm, which is equivalent to a bonding energy of silicon (Si) and a methyl group (Si—CH₃), can easily cut the methyl group.

### <Underlayer Surface Reforming Process Using a Process Liquid Containing an Oxidant>

The surface of the inter-layer insulation film may be reformed by exposing the surface of the inter-layer insulation film to, e.g., a process liquid containing hydrogen peroxide (H₂O₂), and treating the surface of the inter-layer insulation film with a chemical solution. The majority of carbon is removed from the surface of the inter-layer insulation film by the strong oxidizing ability of the hydrogen peroxide. Thus, composition of the surface of the inter-layer insulation film is changed from SiOC to SiO₂. It is therefore possible to densify (increase the density of) the surface of the inter-layer insulation film and to hydrophilize the surface of the inter-layer insulation film from hydrophobicity to hydrophilicity.

### <Heating Process for Making Silicate and Diffusing Manganese>

The heating process for making silicate and diffusing manganese can be performed, e.g., in the process chamber 21d, after a copper film is formed in the process chamber 21c. Examples of the process conditions are as follows.

Wafer temperature: 200 to 500 degrees C.

Process pressure: 13 to 2670 Pa

Process atmosphere: an atmosphere of an inert gas such as N₂, Ar, He or the like (to which a small amount of O₂ gas, e.g., about 10 ppb to 1 volume % of O₂ gas, may be added)

Process time: 30 to 1800 seconds

More suitable process conditions are as follows

Wafer temperature: 350 degrees C.

Process pressure: 1330 Pa

Process atmosphere: an atmosphere of 1% of O2 gas+99% of Ar gas (an oxidizing atmosphere)

Process time: 300 seconds

This heating process can be used in converting a manganese-containing film to silicate and diffusing manganese into a copper film. Alternatively, the heating process may be used only in converting a manganese-containing film to silicate or only in diffusing manganese into a copper film.

### (Example of an Ammonia Gas Supply Method)

When an ammonia gas is selected as a nitrogen-containing reaction gas used for forming a nitrogen-containing manganese film, the following two methods can be used as a method of supplying the ammonia gas.
Supply using an ammonia bombe
Supply using ammonia water (NH₃ (aq))

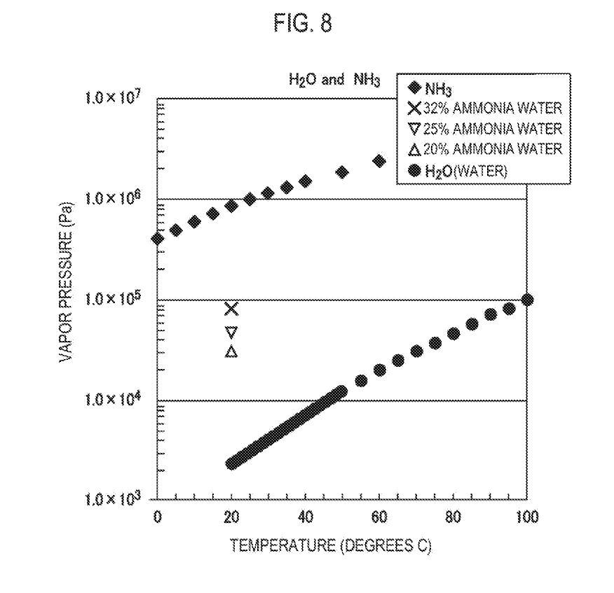

Particularly, the supply using ammonia water is possible for the following reasons. FIG. 8 is a view illustrating vapor pressures of water (H₂O) and ammonia (NH₃). FIG. 8 further illustrates a vapor pressure of ammonia water (32%, 25% and 20%).

As illustrated in FIG. 8, the vapor pressure of ammonia water is two or more orders of magnitude higher than the vapor pressure of water (H₂O). This indicates that the ratio of ammonia to water in the gas is set such that ammonia is more excessive than water. For example, the temperature of ammonia water is set at 20 degrees C. An ammonia gas is generated and extracted from the ammonia water. The ammonia gas thus extracted is used in forming a nitrogen-containing manganese film.

An advantage provided by the supply using ammonia water resides in that, as compared with the supply of a gas containing 100% of ammonia, it becomes easy to take a safety measure which needs to be taken in the apparatus. For example, in the supply using an ammonia bombe, an expensive cylinder cabinet for storing a gas bombe filled with a special gas should be prepared in order to prepare against gas leakage. In contrast, according to the supply using ammonia water, there is no need to prepare an expensive cylinder cabinet. It is only necessary to connect a reservoir for retaining ammonia water to a film-forming apparatus.

In general, the concentration of ammonia water is 10% or more and 35% or less. If the concentration of ammonia water is less than 10%, then specificity of a gas becomes lowered. Thus, there is a possibility that a gas detector otherwise required to handle a specific gas can be omitted.

The method for forming the manganese-containing film described in the first to fourth embodiments can be carried out using the manganese-containing film CVD apparatus 50 described above.

While certain embodiments of the present disclosure have been described above, the present disclosure is not limited to the aforementioned embodiment but may be appropriately reformed without departing from the spirit of the invention.

For example, in the aforementioned embodiments, the copper film 105 is formed using a PVD method. Alternatively, the copper film 105 can be formed by, e.g., a CVD method. In addition, after a thin copper film (seed layer) is formed by a PVD method, a thick copper film can be formed on the thin copper film by an electrolytic plating method or an electroless plating method.

In order to further enhance the adhesion, a liner layer containing ruthenium may be formed between the manganese-containing film and the copper film. For the purpose of improving the burying ability of the copper film, the copper film deposited on the manganese-containing film may be formed by a dry fill method (one kind of Cu reflow in which Cu is sputtered while heating a substrate to a temperature of about 250 degrees C.).

According to the present disclosure, it is possible to provide a method for forming a manganese-containing film, which is capable of improving the adhesion of the film with Cu.

The substrate is not limited to a semiconductor wafer but may be a glass substrate used in manufacturing a solar cell or an FPD.

What is claimed is:

1. A method for forming a manganese-containing film to be formed on an underlayer, comprising:
reacting a manganese compound gas with oxygen supplied from the underlayer to form a manganese oxide film or a manganese silicate film on the underlayer;
reacting a manganese compound gas with a reducing reaction gas, thermally decomposing a manganese compound gas, or performing a decomposition reaction on a manganese compound gas through irradiation of energy or active species to form a metal manganese film on the manganese oxide film or on the manganese silicate film; and
forming a copper film on the metal manganese film.

2. A method for forming a manganese-containing film to be formed on an underlayer, comprising:
reacting a manganese compound gas with a reducing reaction gas, thermally decomposing a manganese compound gas, or performing a decomposition reaction on a manganese compound gas through irradiation of energy or active species to form a metal manganese film on the underlayer;
reacting a manganese compound gas with a nitrogen-containing reaction gas to form a nitrogen-containing manganese film on the metal manganese film; and
forming a copper film on the metal manganese film.

3. A method for forming a manganese-containing film to be formed on an underlayer, comprising:
reacting a manganese compound gas with oxygen supplied from the underlayer to form a manganese oxide film or a manganese silicate film on the underlayer;
reacting a manganese compound gas with a nitrogen-containing reaction gas to form a nitrogen-containing manganese film on the manganese oxide film or one the manganese silicate film; and
forming a copper film on the metal manganese film.

4. The method of claim 1, wherein the manganese compound gas is selected from a group consisting of
a cyclopentadienyl-based manganese compound gas,
a carbonyl-based manganese compound gas,
a beta-diketone-based manganese compound gas,
an amidinate-based manganese compound gas, and
an amideaminoalkane-based manganese compound gas.

5. The method of claim 4, wherein the cyclopentadienyl-based manganese compound gas is a manganese compound gas expressed by a chemical formula Mn(RC₅H₄)₂), where the R is an alkyl group denoted by —C₂H₂₊₁ (n is an integer equal to or greater than 0).

6. The method of claim 4, wherein the carbonyl-based manganese compound gas is selected from a group consisting of
a decacarbonyldimanganese (Mn₂(CO)₁₀) gas,
a methylcyclopentadienyl tricarbonyl manganese ((CH₃C₅H₄)Mn(CO)₃) gas,
a cyclopentadienyl tricarbonyl manganese ((C₅H₅)Mn(CO)₃) gas,
a methylpentacarbonyl manganese (CH₃)Mn(CO)₅) gas, and
a 3-(t-BuAllyl)Mn(CO)₄ gas.

7. The method of claim 4, wherein the beta-diketone-based manganese compound gas is selected from a group consisting of
a bis(dipivaloylmethanato) manganese (Mn(C₁₁H₁₉O₂)₂) gas,
a tris(dipivaloylmethanato) manganese (Mn(C₁₁H₁₉O₂)₃) gas,
a bis(pentanedione) manganese (Mn(C₅H₇O₂)₂) gas,
a tris(pentanedione) manganese (Mn(C₅H₇O₂)₃) gas,
a bis(hexafluoroacetyl) manganese (Mn(C₅HF₆O₂)₂) gas, and
a tris(hexafluoroacetyl) manganese (Mn(C₅HF₆O₂)₃) gas.

8. The method of claim 4, wherein the amidinate-based manganese compound gas is a manganese compound gas expressed by a chemical formula Mn(R¹N—CR³—NR²)₂), where the R¹, R² and R³ are alkyl groups denoted by —CₙH₂ₙ₊₁ (n is an integer equal to or greater than 0).

9. The method of claim 4, wherein the amideaminoalkane-based manganese compound gas is a manganese compound gas expressed by a chemical formula Mn(R¹N—Z—NR²₂)₂), where the R¹ and R² and R³ are alkyl groups denoted by —CₙH₂ₙ₊₁ (n is an integer equal to or greater than 0) and the Z is an alkylene group denoted by —CₙH₂ₙ— (n is an integer equal to or greater than 0).

10. The method of claim 1, further comprising:
performing a heating process for diffusing manganese into the copper film after the copper film is formed.

11. The method of claim 1, further comprising:
performing a heating process for converting the manganese-containing film to silicate after the copper film is formed.

12. The method of claim 1, wherein the underlayer is a Si-containing oxide.

13. The method of claim 1, wherein the metal manganese film is formed by an ALD method in which the manganese compound gas and the reducing reaction gas are alternately supplied with a purge interposed.

14. The method of claim 1, wherein the metal manganese film is formed by an ALD method in which an adsorbed manganese compound is decomposed by irradiation of energy or active species.

15. The method of claim 3, wherein the nitrogen-containing reaction gas is selected from a group consisting of
an ammonia (NH₃) gas,
a hydrazine (NH₂NH₂) gas,
an amine (denoted by a chemical formula NR¹R²R³) gas, and
a hydrazine derivative gas (denoted by a chemical formula R¹R²NNR³R⁴), where the R¹, R², R³ and R⁴ indicate hydrocarbon groups.

16. The method of claim 15, wherein the amine gas is selected from a group consisting of
a methylamine (CH₃NH₂) gas,
an ethylamine (C₂H₅NH₂) gas,
a dimethylamine ((CH₃)₂NH) gas, and
a trimethylamine ((CH₃)₃N) gas.

17. The method of claim 15, wherein the hydrazine derivative gas is selected from a group consisting of
a methylhydrazine (CH₃NNH₃) gas,
a dimethylhydrazine ((CH₃)₂NNH₂) gas, and
a trimethylhydrazine ((CH₃)₃NNH) gas.

18. The method of claim 3, wherein the nitrogen-containing reaction gas is generated using ammonia water.

19. The method of claim 1, wherein at least one of a degassing process by heating, a removal process of a natural copper oxide by hydrogen annealing, an underlayer surface reforming process using irradiation of plasma and/or ions, an underlayer surface reforming process using irradiation of ultraviolet rays, an underlayer surface reforming process using irradiation of a gas cluster ion beam, an underlayer surface reforming process using irradiation of visible light, and an underlayer surface reforming process using a process liquid containing an oxidant, is performed prior to forming the manganese-containing film on the underlayer.
